(19) United States
(12) Patent Application Publication
(10) Pub. No.: US 2018/0047787 A1
(43) Pub. Date: Feb. 15, 2018

(54) Nonvolatile Storage Device and Method of Fabricating Nonvolatile Storage Device

(71) Applicant: TOKYO ELECTRON LIMITED, Tokyo (JP)

(72) Inventors: Genji NAKAMURA, Nirasaki City (JP); Tamotsu MORIMOTO, Nirasaki City (JP)

(21) Appl. No.: 15/670,368

(22) Filed: Aug. 7, 2017

(30) Foreign Application Priority Data
Aug. 9, 2016 (JP) 2016-156135

(51) Int. Cl. H01L 27/24; H01L 45/00

(52) U.S. Cl. CPC H01L 27/2481; H01L 45/1683; H01L 45/1253

(57) ABSTRACT

A nonvolatile storage device includes: first wirings arranged in first and second directions that intersect each other, and extending in a third direction perpendicular to the first and second directions; second wirings extending in the first direction, and each of the second wiring installed at a predetermined interval from each other in the third direction; first layers disposed between the first wirings and the second wirings, and extending in the third direction along the plurality of first wirings; and memory cells installed between the first layers and the second wirings and at respective positions where the first layers and the second wirings intersect each other. Each memory cell includes a second layer disposed towards a side closer to the second wirings and a conductive intermediate layer disposed towards a side closer to the first layers.

### CROSS-REFERENCE TO RELATED APPLICATION

This application is based upon and claims the benefit of priority from Japanese Patent Application No. 2016-156135, filed on Aug. 9, 2016, the entire contents of which are incorporated herein by reference.

### TECHNICAL FIELD

The present disclosure relates to a nonvolatile storage device and a method of fabricating the nonvolatile storage device.

### BACKGROUND

There is known a resistive random access memory (hereinafter, referred to as “ReRAM”) using a resistance change layer, which is capable of keeping a plurality of different resistance states, as a memory element. As for a nonvolatile storage device such as a flash memory and the like, there is also known a technique for arranging memory elements in a three dimension to increase an integration density of the memory elements.

Moreover, there is known a vertical ReRAM using 1R (one-resistor) type memory cells to allow a resistive memory element to have a function of a selector. With such a technique, it is possible to achieve the further integration in the ReRAM having a three-dimensional structure.

In the ReRAM having the 1R type memory cells, however, the memory element and the selector are integrally formed as a single element. As such, a material for the memory element and a material for the selector react with each other, which results in deterioration of the material for the memory element. Therefore, there is a case where in the memory element, a ratio between a resistance value in a low resistance state (hereinafter, referred to as “LRS”) and a resistance value in a high resistance state (hereinafter, referred to as “HRS”) may be lowered. This may make it difficult to write and read out data having the correct values.

Meanwhile, there is known a ReRAM having 1S1R (One Selector One Resistor) type memory cells, each of which has a metallic material interposed between a memory element and a selector. In the ReRAM having the 1S1R type memory cells, a material for the memory element and a material for the selector are not in direct contact with each other, so that the deterioration of the memory element can be suppressed, thereby deriving inherent performance of the memory material and the selector material.

Here, in a case where a vertical ReRAM is configured using 1S1R type memory cells, for example, a ReRAM having a structure shown in FIG. 30 may be considered. FIG. 30 is a longitudinal sectional view illustrating an example of a schematic structure of a ReRAM 100 in a comparative example. As for the ReRAM 100 of the comparative example, electrode layers 101, selector layers 102, intermediate conductive layers 103 and resistance change layers 104 are disposed to penetrate a stack, which includes insulating layers 105 and electrode layers 106 alternately stacked, in a stacked direction of the stack (i.e., in a Z direction in FIG. 30). The plurality of electrode layers 101 extends in the Z direction as shown in FIG. 30, and is arranged in an X direction and a Y direction in FIG. 30. Each of the electrode layers 101 functions, for example, as a bit line. The plurality of electrode layers 106 extends in the X direction as shown in FIG. 30, and is arranged in the Y direction and the Z direction in FIG. 30. Each of the electrode layers 106 functions, for example, as a word line. A region (for example, a region surrounded by dashed lines in FIG. 30) defined by the selector layer 102, the intermediate conductive layer 103 and the resistance change layer 104, which are interposed between one electrode layer 101 and one electrode layer 106, functions as one memory cell.

In each of the memory cells, a write voltage corresponding to a value of data is applied to the resistance change layer 104 interposed between the electrode layer 101 and the electrode layer 106, and a resistance value corresponding to the value of the data is set. Further, in each of the memory cells, when a read voltage is applied to the resistance change layer 104 interposed between the electrode layer 101 and the electrode layer 106, a current flowing through the electrode layer 101 is measured, so that a resistance value set in the resistance change layer 104 is read out as the value of the data.

FIG. 31 is a view illustrating a leakage current. For example, when the data corresponding to a resistance value set in a region 104-1 of the resistance change layer 104 between an electrode layer 106-1 and the electrode layer 101 is read out, a read voltage (for example, V) is applied to the electrode layer 106-1, and the electrode layer 101 is set to 0 V. Accordingly, a certain voltage is applied across a region 102-1 of the selector layer 102 between the electrode layer 106-1 and the electrode layer 101, and the selector layer 102 positioned at the region 102-1 is turned on. In addition, as indicated by a solid arrow in FIG. 31, a current corresponding to the resistance value of the resistance change layer 104 flows from the electrode layer 106-1 to the electrode layer 101 via the resistance change layer 104, the intermediate conductive layer 103 and the selector layer 102. Meanwhile, a non-read voltage (for example, V/2) is applied to another electrode layer 106-2 positioned corresponding to a region 104-2 of the resistance change layer 104, which is not a target to be read out.

Furthermore, by measuring a current flowing through the electrode layer 101, a resistance value of the position of the resistance change layer 104 in the region 104-1 between the electrode layer 106-1 and the electrode layer 101 is measured. If the resistance value of the resistance change layer 104 in the region 104-1 is HRS, the value of the data held in the region 104-1 is determined as, for example, 1. If the resistance value of the resistance change layer 104 in the region 104-1 is LRS, the value of the data held in the region 104-1 is determined as, for example, 0 (zero).

Incidentally, in the ReRAM 100 having the structure shown in FIGS. 30 and 31, the intermediate conductive layer 103 is disposed in common for a plurality of memory cells. As such, as indicated by a dashed arrow in FIG. 31, a current obtained by the voltage applied to the electrode layer 106-2 and the resistance value set in the region 104-2 of the resistance change layer 104 between the electrode layer 106-2 and the electrode layer 101 flows even from another electrode layer 106-2 positioned corresponding to the region 104-2 of the resistance change layer 104, which is not a target to be read out, through the intermediate layer 103 to the region 102-1 of the selector layer 102 which remains turned on. This makes it difficult to accurately measure the resistance value of the region 104-1 of the resistance change layer 104 which is a target to be read out. In particular, when the resistance value of the region 104-1 of the resistance change layer 104 which is a target to be read out is HRS and when the resistance value of the region 104-2 of the resistance change layer 104 which is not a target to be read out is LRS, the influence of a current leaking from the region 104-2 of the resistance change layer 104 which is not a target to be read out is increased.

In the ReRAM 100 having the vertical structure shown in FIGS. 30 and 31, since the intermediate conductive layer 103 is disposed in common for the plurality of memory cells, the voltage V applied from the electrode layer 106-1 to the region 104-1 of the resistance change layer 104, which is a target to be read out, is also applied to the region 104-2 of the resistance change layer 104, which is not a target to be read out, through the intermediate conductive layer 103. Therefore, the voltage V is also applied to a region 102-2 of the selector layer 102 positioned corresponding to the region 104-2 of the resistance change layer 104 which is not a target to be read out, thereby turning the region 102-2 of the selector layer 102 on as well. Accordingly, a current obtained by the voltage applied to the electrode layer 106-2 and the resistance value set in the region 104-2 of the resistance change layer 104 between the electrode layer 106-2 and the electrode layer 101 flows even from the other electrode layer 106-2 positioned corresponding to the region 104-2 of the resistance change layer 104, which is not a target to be read out, through the intermediate layer 103 and the selector layer 102 to the electrode layer 101. Thus, in the ReRAM 100 having the vertical structure shown in FIGS. 30 and 31, it is difficult to correctly read out information set in each of the memory cells.

### SUMMARY

Some embodiments of the present disclosure provide a technique capable of correctly reading out information set in each of memory cells of a vertical ReRAM.

According to one embodiment of the present disclosure, there is provided a nonvolatile storage device, including: a plurality of first wirings arranged in a first direction and a second direction that intersect each other, and extending in a third direction perpendicular to the first direction and the second direction; a plurality of second wirings extending in the first direction, and each of the plurality of second wiring installed at a predetermined interval from each other in the third direction; a plurality of first layers disposed between the plurality of first wirings and the plurality of second wirings, and extending in the third direction along the plurality of first wirings; and a plurality of memory cells installed between the plurality of first layers and the plurality of second wirings and at respective positions where the plurality of first layers and the plurality of second wirings intersect each other, wherein each of the plurality of memory cells includes a second layer disposed towards a second wiring side closer to the plurality of second wirings and a conductive intermediate layer disposed towards a first layer side closer to the plurality of first layers, the intermediate layer in one of the memory cells is insulated from the intermediate layer in another memory cell of the memory cells adjacent to the one of the memory cells by an insulating layer, each of the plurality of first layers is one of a memory layer configured to hold a resistance value that changes depending on a voltage applied, as a data, and a selector layer configured to control a selection and a non-selection of each of the plurality of memory cells, and the second layer is the other of the memory layer and the selector layer.

According to another embodiment of the present disclosure, there is provided a method of fabricating a nonvolatile storage device, which includes: forming an opening in a multi-layered film in a stacked direction of the multi-layered film, the multi-layered film having a plurality of insulating layers and a plurality of metal layers alternately stacked; etching the plurality of metal layers on an inner wall of the opening in a plane direction of the multi-layered film; stacking a first layer along the inner wall of the opening; filling the opening with a first conductive material; etching the first conductive material filled into the opening so that the plurality of insulating layers are exposed, and forming the opening again; stacking a second layer along the inner wall of the opening; and filling the opening with a second conductive material, wherein the first layer is one of a memory layer configured to hold a resistance value that changes depending on a voltage applied thereto, as data, and a selector layer configured to control a selection and a non-selection of the memory layer, and the second layer is the other of the memory layer and the selector layer.

According to another embodiment of the present disclosure, there is provided a method of fabricating a nonvolatile storage device, which includes: forming a first opening in a multi-layered film in a stacked direction of the multi-layered film, the multi-layered film having a plurality of insulating layers and a plurality of sacrificial layers alternately stacked; stacking a first layer along an inner wall of the first opening; filling the first opening with a first conductive material; forming a second opening in the multi-layered film in the stacked direction of the multi-layered film, the second opening being formed at a second position different from a first position where the first opening is formed; removing the plurality of sacrificial layers; filling areas between the plurality of insulating layers where the plurality of sacrificial layers had been disposed, with a second conductive material; etching the second conductive material at the second position, so that the plurality of insulating layers are exposed, and forming the second opening again; etching the second conductive material on an inner wall of the second opening in a plane direction of the multi-layered film; filling areas between the plurality of insulating layers with a third material for forming a second layer in the second opening; etching the third material filled into the second opening, so that the plurality of insulating layers are exposed, and forming the second opening again; etching the third material on the inner wall of the second opening in the plane direction of the multi-layered film, to form the second layer; filling the second opening with a fourth conductive material; etching the fourth conductive material at the second position, so that the plurality of insulating layers are exposed, and forming the second opening again; and filling the second opening with an insulating material, wherein the first layer is one of a memory layer configured to hold a resistance value that changes depending on a voltage applied, as a data, and a selector layer configured to control a selection and a non-selection of the memory layer, and the second layer is the other of the memory layer and the selector layer.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal sectional view illustrating a first embodiment of a schematic structure of a ReRAM of First embodiment.

FIG. 2 is a view illustrating an example of a section taken along line A-A in the ReRAM shown in FIG. 1.

FIG. 3 is a flowchart showing an example of a procedure for fabricating the ReRAM of the first embodiment.

FIG. 4 is a longitudinal sectional view illustrating an example of a fabricating process of the ReRAM of the first embodiment.

FIG. 5 is a longitudinal sectional view illustrating an example of a fabricating process of the ReRAM of the first embodiment.

FIG. 6 is a longitudinal sectional view illustrating an example of a fabricating process of the ReRAM of the first embodiment.

FIG. 7 is a longitudinal sectional view illustrating an example of a fabricating process of the ReRAM of the first embodiment.

FIG. 8 is a longitudinal sectional view illustrating an example of a fabricating process of the ReRAM of the first embodiment.

FIG. 9 is a view illustrating an example of a section taken along line C-C in the ReRAM shown in FIG. 8.

FIG. 10 is a longitudinal sectional view illustrating an example of a fabricating process of the ReRAM of the first embodiment.

FIG. 11 is a longitudinal sectional view illustrating an example of a fabricating process of the ReRAM of the first embodiment.

FIG. 12 is a view illustrating an example of a section taken along line D-D in the ReRAM shown in FIG. 11.

FIG. 13 is a longitudinal sectional view illustrating an example of a fabricating process of the ReRAM of the first embodiment.

FIG. 14 is a view illustrating an example of a section taken along line E-E in the ReRAM shown in FIG. 13.

FIG. 15 is a longitudinal sectional view illustrating another example of a schematic structure of the ReRAM of the first embodiment.

FIG. 16 is a longitudinal sectional view illustrating an example of a schematic structure of a ReRAM of a second embodiment.

FIG. 17 is a view illustrating an example of a section taken along line F-F in the ReRAM shown in FIG. 16.

FIG. 18 is a flowchart showing an example of a procedure for fabricating the ReRAM of the second embodiment.

FIG. 19 is a longitudinal sectional view illustrating an example of a fabricating process of the ReRAM according to the second embodiment.

FIG. 20 is a longitudinal sectional view illustrating an example of a fabricating process of the ReRAM according to the second embodiment.

FIG. 21 is a longitudinal sectional view illustrating an example of a fabricating process of the ReRAM according to the second embodiment.

FIG. 22 is a longitudinal sectional view illustrating an example of a fabricating process of the ReRAM according to the second embodiment.

FIG. 23 is a longitudinal sectional view illustrating an example of a fabricating process of the ReRAM according to the second embodiment.

FIG. 24 is a longitudinal sectional view illustrating an example of a fabricating process of the ReRAM according to the second embodiment.

FIG. 25 is a longitudinal sectional view illustrating an example of a fabricating process of the ReRAM according to the second embodiment.

FIG. 26 is a longitudinal sectional view illustrating an example of a fabricating process of the ReRAM according to the second embodiment.

FIG. 27 is a longitudinal sectional view illustrating an example of a fabricating process of the ReRAM according to the second embodiment.

FIG. 28 is a longitudinal sectional view illustrating an example of a fabricating process of the ReRAM according to the second embodiment.

FIG. 29 is a longitudinal sectional view illustrating another example of a schematic structure of the ReRAM according to the second embodiment.

FIG. 30 is a longitudinal sectional view illustrating an example of a schematic structure of a ReRAM in a comparative example.

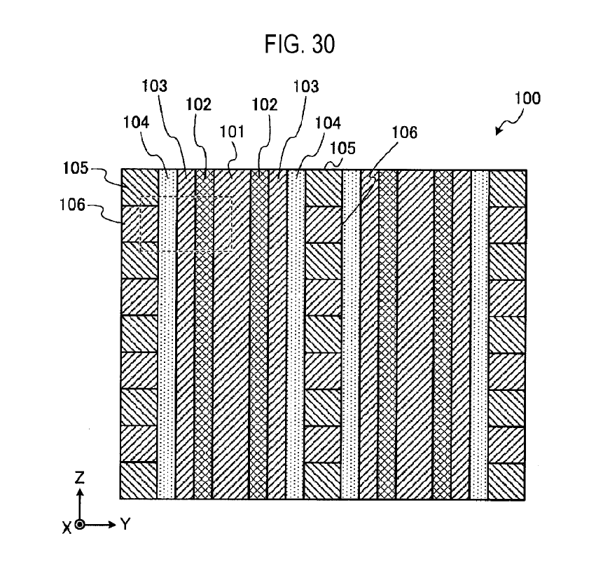

FIG. 31 is a view illustrating a leakage current.

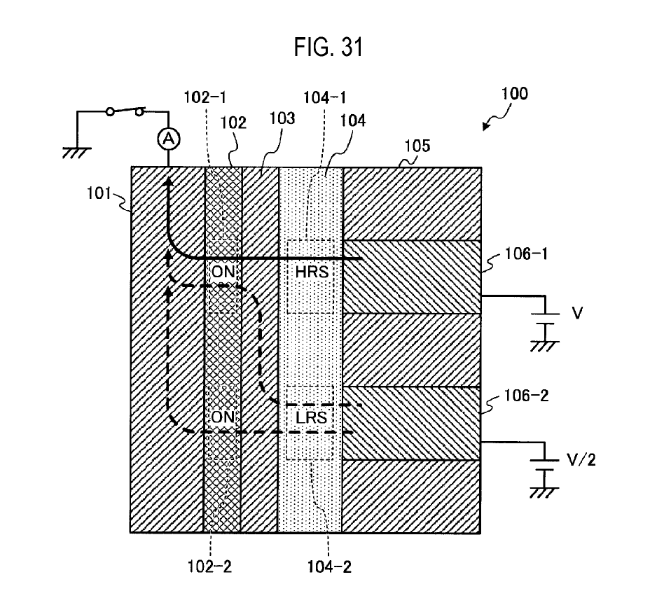

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In one embodiment, a nonvolatile storage device disclosed herein includes a plurality of first wirings, a plurality of second wirings, a plurality of first layers, and a plurality of memory cells. The first wirings are arranged in a first direction and a second direction that intersect each other, and extend in a third direction perpendicular to the first direction and the second direction. The second wirings extend in the first direction and are installed at a predetermined interval in the third direction. The first layers are respectively disposed between the plurality of first wirings and the plurality of second wirings and extend in the third direction along the plurality of first wirings. The memory cells are installed between the plurality of first layers and the plurality of second wirings and at respective positions where the plurality of first layers and the plurality of second wirings intersect each other. In addition, each of the plurality of memory cells includes a second layer disposed at each of the plurality of second wirings side and a conductive intermediate layer disposed at each of the plurality of first layers side. The intermediate layer in one of the memory cells adjacent each other is insulated from the intermediate layer in the other of the memory cells adjacent each other by an insulating layer. Each of the plurality of first layers is one of a memory layer configured to hold a resistance value that changes depending on a voltage applied thereto, as data, and a selector layer configured to control selection and non-selection of each of the plurality of memory cell. The second layer is the other of the memory layer and the selector layer.

In one embodiment of the disclosed nonvolatile storage device, the respective memory cells are insulated from one another by insulating layers. The second layer in each of the memory cells may be disposed between the intermediate layer and the second wiring and between the intermediate layer and the insulating layer.

In one embodiment of the disclosed nonvolatile storage device, an intermediate layer may be disposed between the first layer and the second layer in each of the memory cells.

In one embodiment, a method of fabricating the nonvolatile storage device described herein includes: forming an opening in a multi-layered film in a stacked direction of the multi-layered film, the multi-layered film having a plurality of insulating layers and a plurality of metal layers alternately stacked; etching the plurality of metal layers on an inner wall of the opening in a plane direction of the multi-layered film; stacking a first layer along the inner wall of the opening; filling the opening with a first conductive material; etching the first conductive material filled into the opening so that the plurality of insulating layers are exposed, and forming the opening again; stacking a second layer along the inner wall of the opening; and filling the opening with a second conductive material. In addition, the first layer is one of a memory layer configured to hold a resistance value that changes depending on a voltage applied thereto, as data, and a selector layer configured to control selection and non-selection of the memory layer, and the second layer is the other of the memory layer and the selector layer.

In one embodiment, a method of fabricating the nonvolatile storage device described herein includes: forming a first opening in a multi-layered film in a stacked direction of the multi-layered film, the multi-layered film having a plurality of insulating layers and a plurality of sacrificial layers alternately stacked; stacking a first layer along an inner wall of the first opening; filling the first opening with a first conductive material; forming a second opening in the multi-layered film in the stacked direction of the multi-layered film, the second opening being formed at a position different from a position where the first opening is formed; removing the plurality of sacrificial layers; filling areas between the plurality of insulating layers where the plurality of sacrificial layers had been disposed, with a second conductive material; etching the second conductive material at the position of the second opening, so that the plurality of insulating layers are exposed, and forming the second opening again; etching the second conductive material on an inner wall of the second opening in a plane direction of the multi-layered film; filling areas between the plurality of insulating layers with a third conductive material for forming a second layer in the second opening; etching the third conductive material filled into the second opening, so that the plurality of insulating layers are exposed, and forming the second opening again; etching the third conductive material on the inner wall of the second opening in a plane direction of the multi-layered film, to form the second layer; filling the second opening with a fourth conductive material; etching the fourth conductive material at the position of the second opening, so that the plurality of insulating layers are exposed, and forming the second opening again; and filling the second opening with an insulating material. The first layer is one of a memory layer configured to hold a resistance value that changes depending on a voltage applied thereto, as data, and a selector layer configured to control selection and non-selection of the memory layer, and the second layer is the other of the memory layer and the selector layer.

Hereinafter, embodiments of the nonvolatile storage device and the method of fabricating the nonvolatile storage device disclosed herein will be described in detail with reference to the drawings. The nonvolatile storage device and the method of fabricating the nonvolatile storage device are not limited to the embodiments described herein.

### First Embodiment

### <Structure of ReRAM>

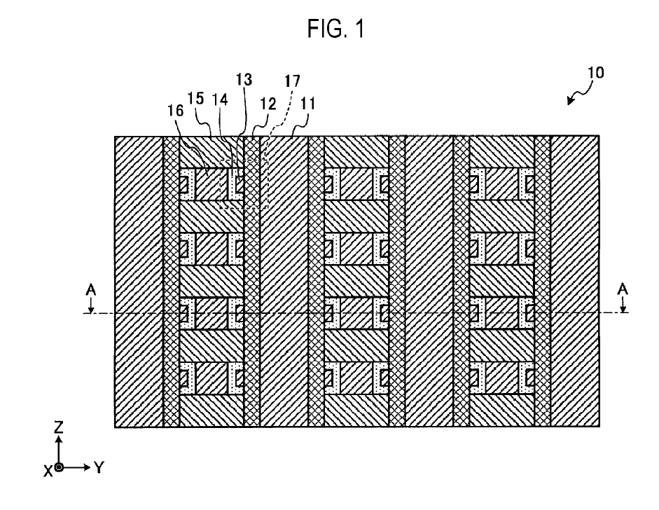

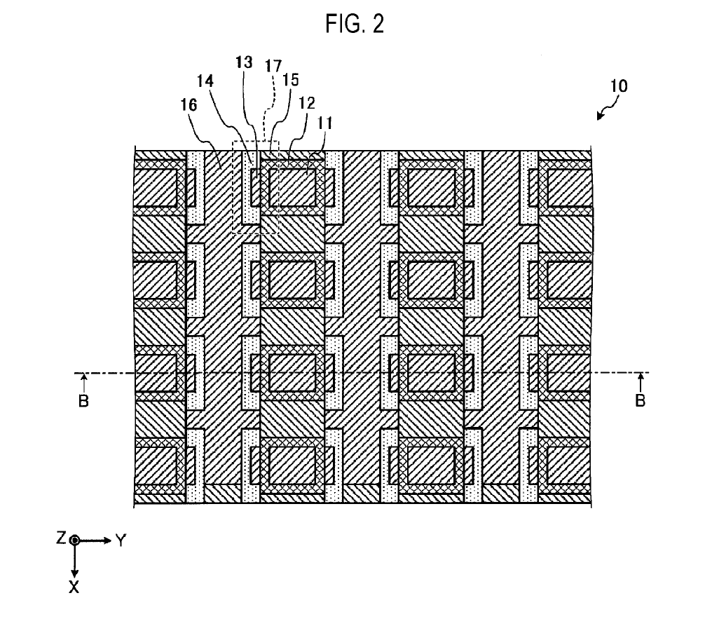

FIG. 1 is a longitudinal sectional view illustrating an example of a schematic structure of a ReRAM 10 according to a first embodiment. FIG. 2 is a view illustrating an example of a section taken along line A-A in the ReRAM 10 shown in FIG. 1. A section B-B of the ReRAM 10 shown in FIG. 2 corresponds to FIG. 1. The ReRAM 10 of the first embodiment includes a plurality of electrode layers 11, a plurality of selector layers 12, a plurality of electrode layers 16 and a plurality of memory cells 17. The plurality of electrode layers 11 are arranged in an X direction and a Y direction in FIG. 1 and extend in a Z direction in FIG. 1. The electrode layer 11 functions as, for example, a bit line. The electrode layer 11 is one example of the first wiring. Further, the X direction is one example of a first direction, the Y direction is one example of a second direction, and the Z direction is one example of a third direction.

The plurality of electrode layers 16 extend in the X direction in FIG. 1 and are arranged at a predetermined interval in the Z direction in FIG. 1. Each of the electrode layers 16 functions as, for example, a word line. Each of the selector layers 12 is arranged between the electrode layer 11 and the electrode layer 16 and extends along the electrode layer 11 in the Z direction in FIG. 1. Each of the memory cells 17 is placed between the selector layer 12 and the electrode layer 16 and at a position where the selector layer 12 and the electrode layer 16 intersect each other. Each of the memory cells 17 includes an intermediate conductive layer 13 disposed towards a side closer to the selector layer 12 and a resistance change layer 14 disposed towards a side closer to the electrode layer 16.

In this embodiment, for example, as shown in FIG. 1, the intermediate conductive layers 13 of the respective memory cells 17 neighboring in the Z direction are electrically insulated by an insulating layer 15 formed of an insulating material. The insulating layer 15 is formed of, for example, silicon oxide, silicon nitride or the like.

The electrode layer 11, the intermediate conductive layer 13 and the electrode layer 16 are composed of a metal. In addition, the electrode layer 11, the intermediate conductive layer 13 and the electrode layer 16 may be configured with a metallic material, for example, W, WN, TiN, Cu, Al, Mo, Ta, TaN, silicide or the like, which can be processed by a semiconductor process such as CVD (chemical vapor deposition), ALD (atomic layer deposition) or the like. The electrode layer 11 is one example of the first wiring, the intermediate conductive layer 13 is one example of the intermediate layer and the electrode layer 16 is one example of the second wiring.

Each of the selector layers 12 is, for example, an ovonic threshold switch (OTS) that functions as a varistor, and is made of, for example, a chalcogenide material containing at least elements of Group 16 in the Periodic Table, specifically, chalcogen elements such as O, S, Se, Te and the like. The selector layer 12 is one example of the first layer.

Each of the resistance change layers 14 is configured by a resistance change material capable of switching between a high resistance state (“HRS”) and a law resistance state (“LRS”) depending on the polarity of a voltage applied thereto. As the resistance change material, for example, a metal oxide containing at least one element of Al, Ti, Hf, Zr, Nb and Ta may be used. The resistance change layer 14 is one example of the memory layer and the second layer.

In the ReRAM 10 according to this embodiment, the intermediate conductive layers 13 in the respective memory cells 17 are electrically insulated from one another by the insulating layers 15. Accordingly, a current flowing from the electrode layer 16 to the electrode layer 11 via the resistance change layer 14, the intermediate conductive layer 13 and the selector layer 12 does not flow into another intermediate conductive layer 13. Thus, a current corresponding to a resistance value of the intermediate conductive layer 13 inside the selected memory cell 17 is detected in the electrode layer 11 so that information set in the respective memory cell 17 is correctly read out.

Furthermore, since the intermediate conductive layers 13 in the respective memory cells 17 are electrically insulated from one another by the insulating layers 15, a voltage applied to each of the intermediate conductive layers 13 by the electrode layer 16 does not affect another intermediate conductive layer 13. Therefore, when a voltage for selection is applied by the electrode layer 16, a selector layer 12 located at a position corresponding to the respective electrode layer 16 is turned on, whereas when a voltage for non-selection is applied by the electrode layer 16, the selector layer 12 located at the position corresponding to the respective electrode layer 16 is maintained in an turn-off state. Thus, it is possible to suppress a leakage current flowing through the selector layer 12 located at a position corresponding to a non-selected electrode layer 16. Accordingly, a current corresponding to a resistance value of the intermediate conductive layer 13 inside the selected memory cell 17 is detected in the electrode layer 11 so that the information set in the respective memory cell 17 is correctly read out.

### <Procedure for Fabricating ReRAM>

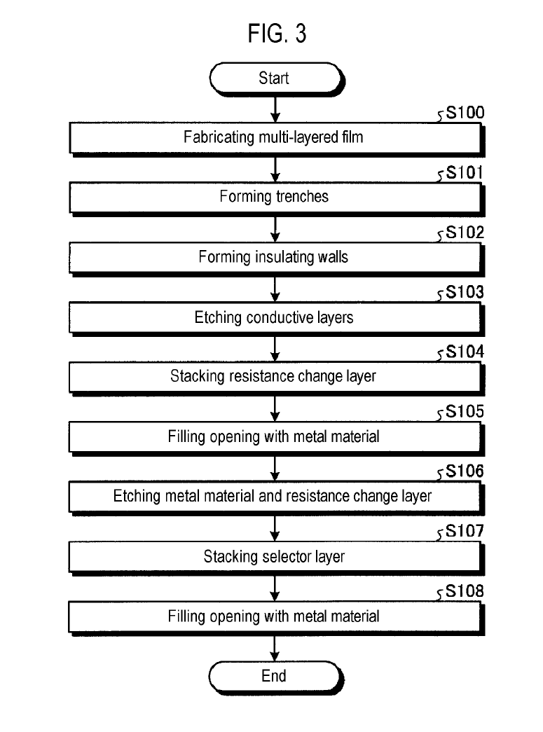

Next, a procedure for fabricating the ReRAM 10 of this embodiment will be described with reference to FIGS. 3 to 14. FIG. 3 is a flowchart showing an example of the procedure for fabricating the ReRAM 10 according to the first embodiment.

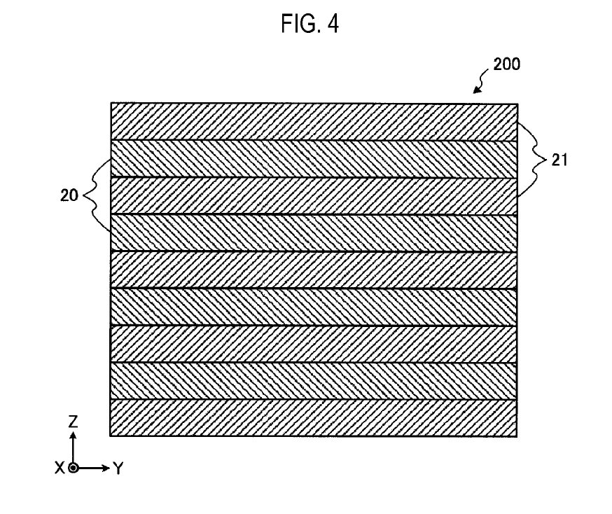

First, for example, as shown in FIG. 4, a multi-layered film 200 with conductive layers 20 and insulating layers 21 alternately stacked is formed (S100). In the multi-layered film 200 shown in FIG. 4, the conductive layer 20 is a metal film and is formed of the material used for forming the electrode layer 16, such as TiN, W, Cu or the like. In addition, the insulating layer 21 is formed of the material used for forming the insulating layer 15, such as SiN, SiO₂ or the like. The multi-layered film 200 shown in FIG. 4 is prepared by, for example, a process such as PVD, CVD, ALD or the like. In the multi-layered film 200 shown in FIG. 4, a stacked direction is defined as the Z direction, a direction perpendicular to the paper in FIG. 4 in a plane of each layer is defined as the X direction, and a direction parallel to the paper in FIG. 4 is defined as the Y direction.

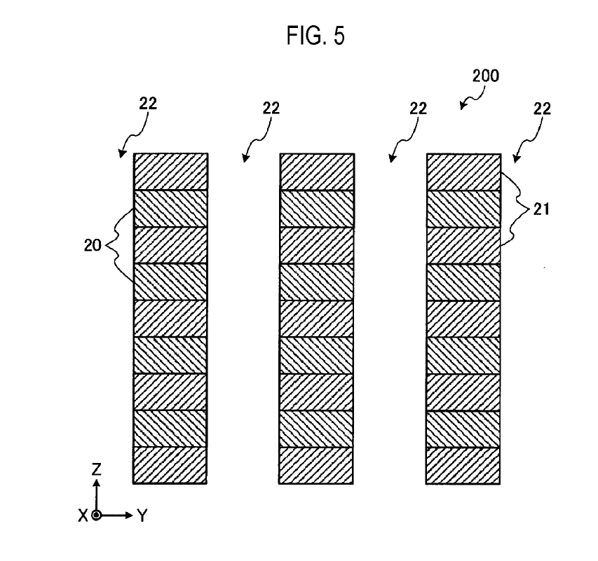

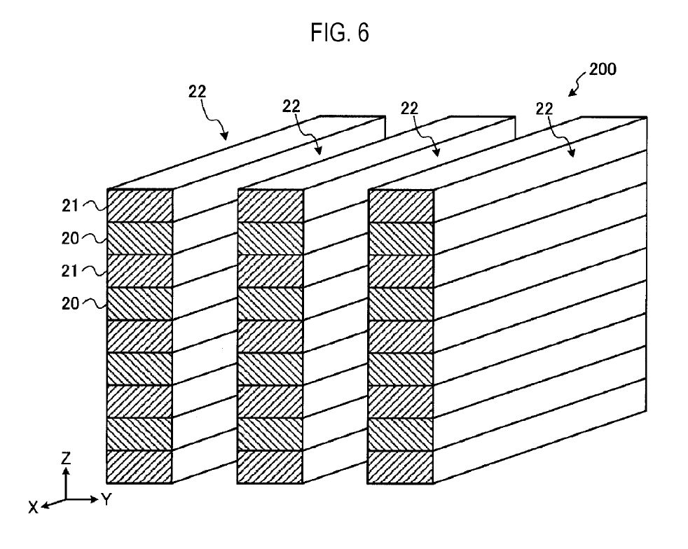

Subsequently, for example, as shown in FIGS. 5 and 6, a plurality of trenches 22 extending in the X direction and the Z direction are formed in the Y direction in the multi-layered film 200 (S101). The trenches 22 are formed by, for example, anisotropic etching such as a reactive ion etching (RIE) or the like.

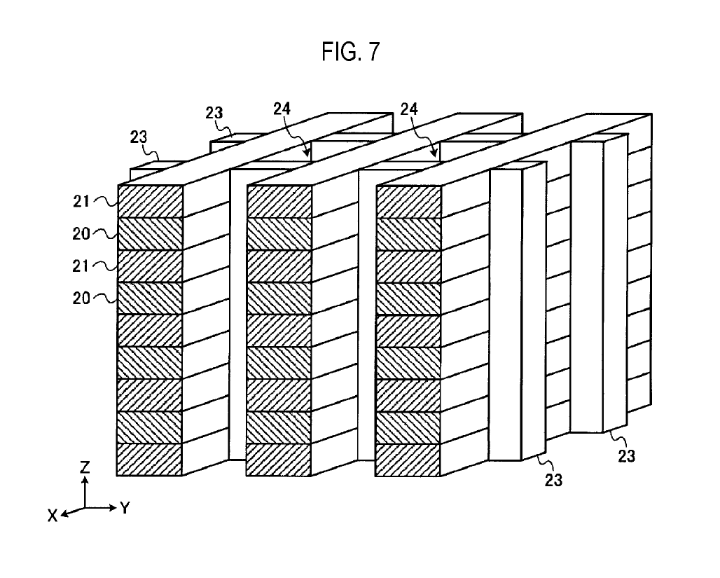

Subsequently, each of the trenches 22 is filled with an insulating material such as SiO₂. Thereafter, the insulating materials with which the trenches 22 have been filled are removed at a predetermined interval in the X direction. The insulating materials are removed by, for example, anisotropic etching such as a reactive ion etching (RIE) or the like. Accordingly, for example, as shown in FIG. 7, portions of the residual insulating materials are formed as insulating walls 23 in the respective trenches 22 (S102). Further, by removing portions of the insulating materials with which the trenches 22 have been filled, a plurality of openings 24 surrounded by the multi-layered film 200 and the insulating walls 23 are formed, for example, as shown in FIG. 7. At an inner wall of each of the openings 24, the conductive layer 20 and the insulating layer 21 in addition to sidewalls of the insulating walls 23 are exposed.

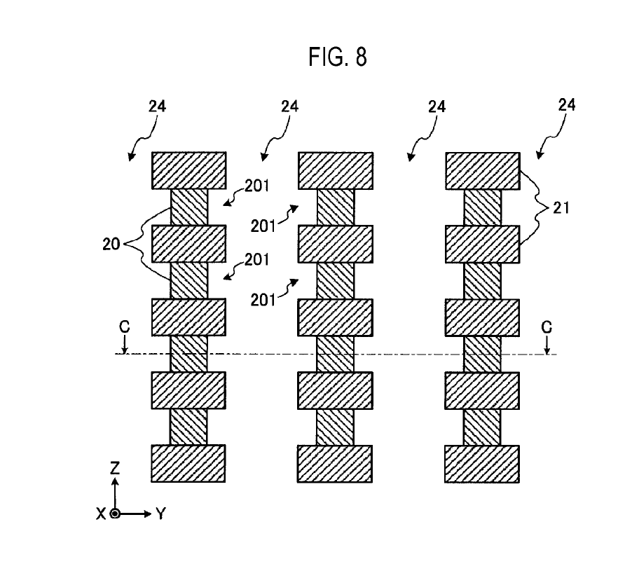

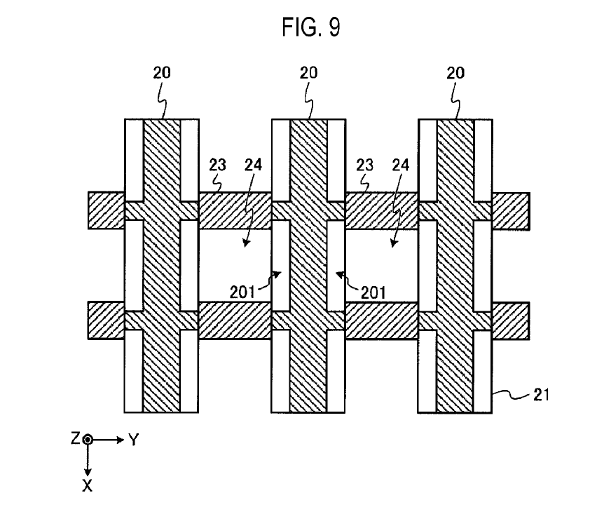

Thereafter, the conductive layers 20 are etched (S103). For example, an isotropic etching such as a wet etching is used in etching the conductive layers 20. Accordingly, as shown in FIGS. 8 and 9, each of the conductive layers 20 is etched in the X direction and the Y direction, i.e., a plane direction of the multi-layered film 200 so that the recesses 201 are respectively formed in the conductive layers 20. Each of the recesses 201 is concaved in the X direction and the Y direction as compared with the insulating layer 21. FIG. 9 is a view illustrating an example of a section taken along line C-C in the ReRAM 10 shown in FIG. 8.

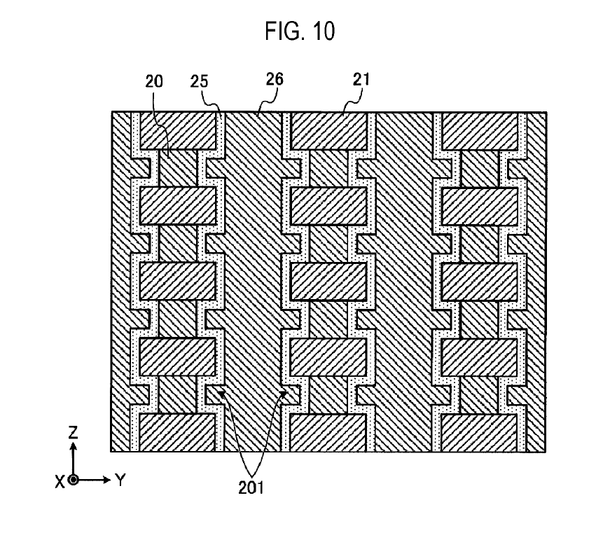

Subsequently, for example, as shown in FIG. 10, a resistance change layer 25 is stacked along an inner wall of each of the openings 24 (S104). Therefore, the resistance change layer 25 is stacked on the inner wall of each of the openings 24 along the recess 201 of the conductive layer 20. The resistance change layer 25 is formed of the material used for forming the resistance change layer 14, for example, HfO or the like. The resistance change layer 25 is stacked along the inner wall of the opening 24 by, for example, CVD, ALD or the like.

Thereafter, for example, as shown in FIG. 10, each of the openings 24 with the resistance change layer 25 stacked therein is filled with a metal material 26 (S105). Accordingly, the resistance change layer 25 and the metal material 26 are stacked on the inner wall of each of the openings 24 along the recess 201 of the conductive layer 20. The metal material 26 with which the opening 24 is filled is the metal material used for forming the intermediate conductive layer 13. The metal material 26 is one example of the first conductive material.

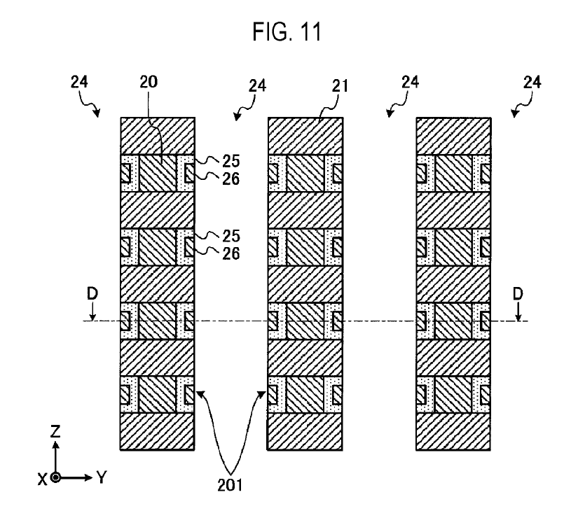

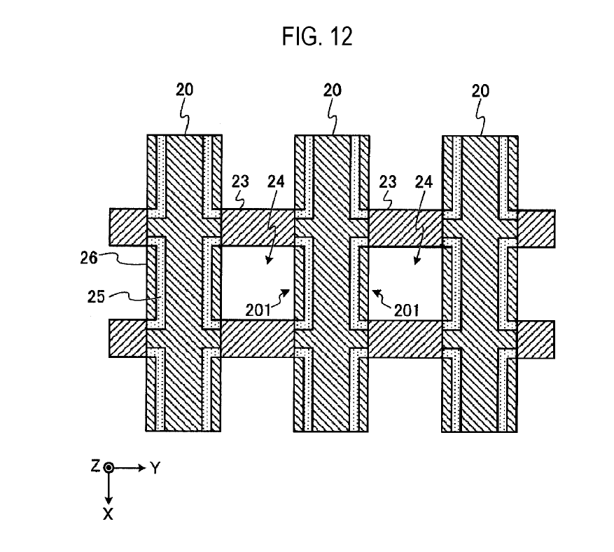

Subsequently, for example, as shown in FIGS. 11 and 12, the resistance change layer 25 and the metal material 26 are etched to form the opening 24 again (S106). FIG. 12 is a view illustrating an example of a section taken along line D-D in the ReRAM 10 shown in FIG. 11. In the etching in step S106, the resistance change layer 25 and the metal material 26 are etched to expose the insulating layer 21 at the inner wall of each of the openings 24. The resistance change layer 25 and the metal material 26 are removed by, for example, an anisotropic etching such as RIE or the like. Therefore, for example, as shown in FIG. 11, the resistance change layers 25 and the metal materials 26 formed in the recesses 201 of the respective conductive layers 20 are separated from one another in the Z direction by the respective insulating layers 21 interposed between the conductive layers 20.

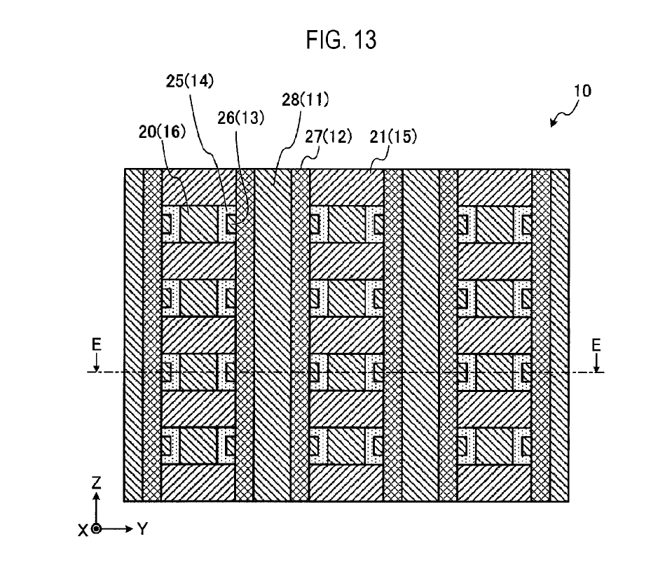

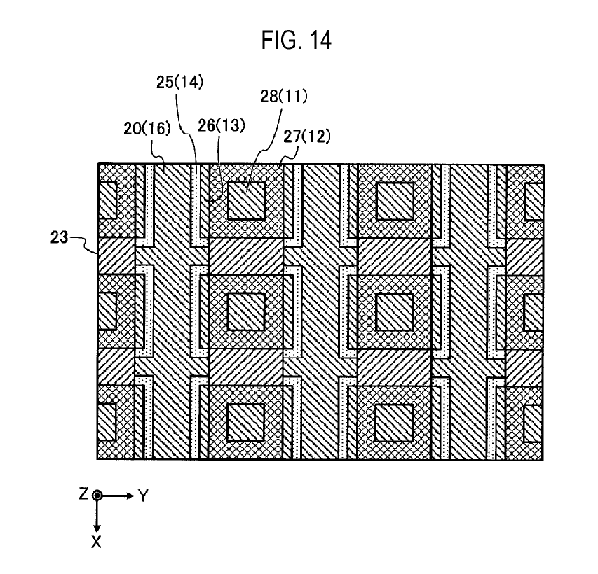

Thereafter, for example, as shown in FIGS. 13 and 14, a selector layer 27 is stacked along the inner wall of each of the openings 24 (S107). FIG. 14 is a view illustrating an example of a section taken along line E-E in the ReRAM 10 shown in FIG. 13. The selector layer 27 is formed of, for example, the material used for forming the selector layer 12, such as a chalcogenide material or the like. The selector layer 27 is stacked along the inner wall of the opening 24 by, for example, CVD, ALD or the like.

Subsequently, for example, as shown in FIGS. 13 and 14, the opening 24 with the selector layer 27 stacked therein is filled with a metal material 28 (S108). The metal material 28 is one example of the second conductive material. In this way, the ReRAM 10 of this embodiment is fabricated. In addition, the metal material 28 functions as the electrode layer 11, the selector layer 27 functions as the selector layer 12, and the metal material 26 functions as the intermediate conductive layer 13. Further, the resistance change layer 25 functions as the resistance change layer 14, the insulating layer 21 functions as the insulating layer 15, and the conductive layer 20 functions as the electrode layer 16.

The ReRAM 10 according to the first embodiment has been described above. As is apparent from the foregoing description, according to the ReRAM 10 of this embodiment, the intermediate conductive layers 13 in the respective memory cells 17 are electrically insulated from one another by the respective insulating layers 15. Therefore, a current flowing from each of the electrode layers 16 to the electrode layer 11 through the resistance change layer 14, the intermediate conductive layer 13 and the selector layer 12 does not flow into another intermediate conductive layer 13. Accordingly, a current corresponding to a resistance value of the intermediate conductive layer 13 in the selected memory cell 17 is detected in the electrode layer 11, so that information set in the respective memory cell 17 is correctly read out.

In addition, since the intermediate conductive layers 13 in the respective memory cells 17 are electrically insulated from one another by the insulating layers 15, it is possible to suppress a leakage current through a selector layer 12 located at a position corresponding to a non-selected electrode layer 16. As a result, a current corresponding to a resistance value of the intermediate conductive layer 13 in the selected memory cell 17 is detected in the electrode layer 11, so that information set in the respective memory cell 17 is correctly read out. Moreover, the suppression of the leakage current restrains power consumption of the ReRAM 10.

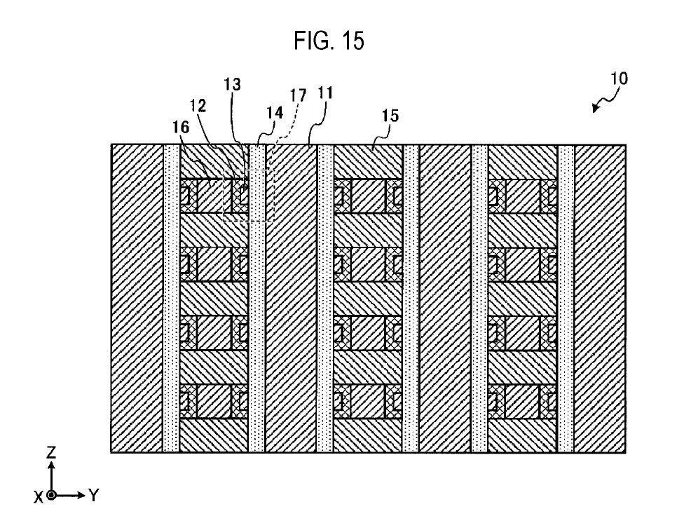

In each of the memory cells 17 of the ReRAM 10 of the first embodiment described above, the resistance change layer 14 is disposed towards the side closer to the electrode layer 16 and the selector layer 12 is disposed towards the side closer to the electrode layer 11 with the intermediate conductive layer 13 disposed between the resistance change layer 14 and the selector layer 12. However, the disclosed technique is not limited thereto. In each of the memory cells 17, for example, as shown in FIG. 15, the selector layer 12 may be disposed towards the side closer to the electrode layer 16 and the resistance change layer 14 may be disposed towards the side closer to the electrode layer 11 with the intermediate conductive layer 13 disposed between the selector layer 12 and the resistance change layer 14.

### Second Embodiment

### <Structure of ReRAM>

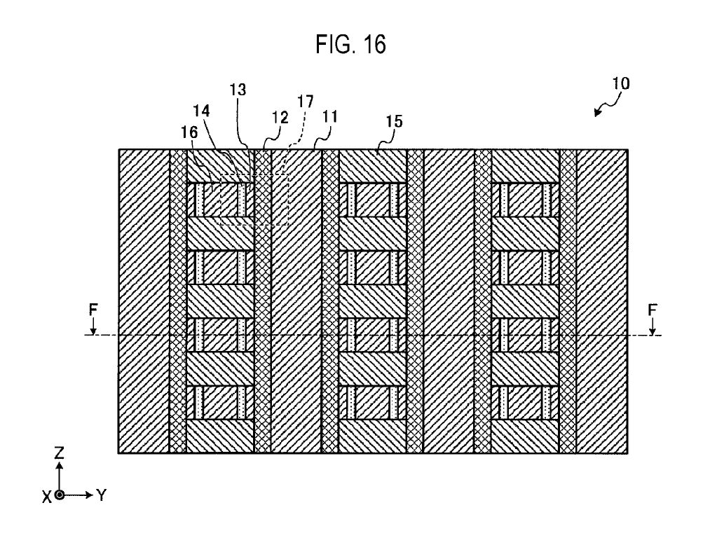

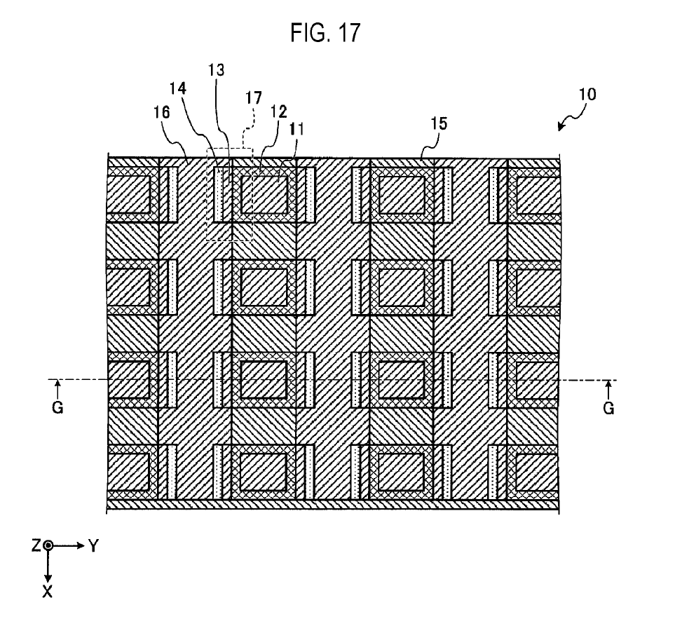

FIG. 16 is a longitudinal sectional view illustrating an example of a schematic structure of a ReRAM 10 according to a second embodiment. FIG. 17 is a view illustrating an example of a section taken along line F-F in the ReRAM 10 shown in FIG. 16. A section G-G of the ReRAM 10 shown in FIG. 17 corresponds to FIG. 16. The ReRAM 10 of the second embodiment includes a plurality of electrode layers 11, a plurality of selector layers 12, a plurality of electrode layers 16 and a plurality of memory cells 17. Each of the memory cells 17 includes an intermediate conductive layer 13 disposed towards the side closer to the selector layer 12 and a resistance change layer 14 disposed towards the side closer to the electrode layer 16. Components in FIGS. 16 and 17 denoted by the same reference numerals as components in FIGS. 1 and 2 have functions equal to or similar to those of the components shown in FIGS. 1 and 2 except for matters to be described below, and therefore, descriptions thereof will be omitted.

Since the intermediate conductive layer 13 is interposed between the selector layer 12 and the resistance change layer 14 in each of the memory cells 17 in this embodiment, the selector layer 12 and the resistance change layer 14 are not in direct contact with each other. Here, if the selector layer 12 and the resistance change layer 14 are in direct contact with each other, a material for the selector layer 12 and a material for the resistance change layer 14 may affect each other at an interface where the selector layer 12 is in contact with the resistance change layer 14. For example, if the resistance change layer 14 is made of a metal oxide, the selector layer 12 may be oxidized by oxygen diffused from the resistance change layer 14 via the interface where the selector layer 12 and the resistance change layer 14 are in contact with each other. This may deteriorate a switching property of the selector layer 12. Even in the resistance change layer 14, elements contained in the selector layer 12 are diffused into the resistance change layer 14 via the interface where the selector layer 12 and the resistance change layer 14 are in contact with each other, so that properties of the resistance change layer 14 may be changed and a ratio of resistance values in HRS and LRS of the resistance change layer 14 may be lowered.

On the contrary, since the intermediate conductive layer 13 is interposed between the selector layer 12 and the resistance change layer 14 in this embodiment, the selector layer 12 and the resistance change layer 14 are not in direct contact with each other. Therefore, no reaction occurs between the materials for the selector layer 12 and the resistance change layer 14. Accordingly, the deterioration of the switching property of the selector layer 12 and the reduction in the ratio of the resistance values of the resistance change layer 14 are prevented. In some embodiments, the intermediate conductive layer 13 interposed between the selector layer 12 and the resistance change layer 14 may be composed of a material having conductivity and low reactivity with any of the selector layer 12 and the resistance change layer 14.

Specifically, the intermediate conductive layer 13 may be composed of a noble metal such as Au, Ag, Pt or the like.

Even in the ReRAM 10 of this embodiment, the intermediate conductive layers 13 of the respective memory cells 17 are electrically insulated from one another by the insulating layers 15. Accordingly, a current flowing from each of the electrode layers 16 to the electrode layer 11 via the resistance change layer 14, the intermediate conductive layer 13 and the selector layer 12 does not flow into another intermediate conductive layer 13. Therefore, a current corresponding to a resistance value of the intermediate conductive layer 13 in the selected memory cell 17 is detected in the electrode layer 11, so that information set in the respective memory cell 17 is correctly read out.

Furthermore, since the intermediate conductive layers 13 in the respective memory cells 17 are electrically insulated from one another by the insulating layers 15, a voltage applied to each of the intermediate conductive layers 13 by the electrode layers 16 does not affect another intermediate conductive layer 13. Accordingly, it is possible to suppress a leakage current through a selector layer 12 located at a position corresponding to a non-selected electrode layer 16. Therefore, a current corresponding to a resistance value of the intermediate conductive layer 13 in the selected memory cell 17 is detected in the electrode layer 11, so that information set in the respective memory cell 17 is correctly read out. In addition, the suppression of the leakage current restrains power consumption of the ReRAM 10.

### <Procedure for Fabricating ReRAM>

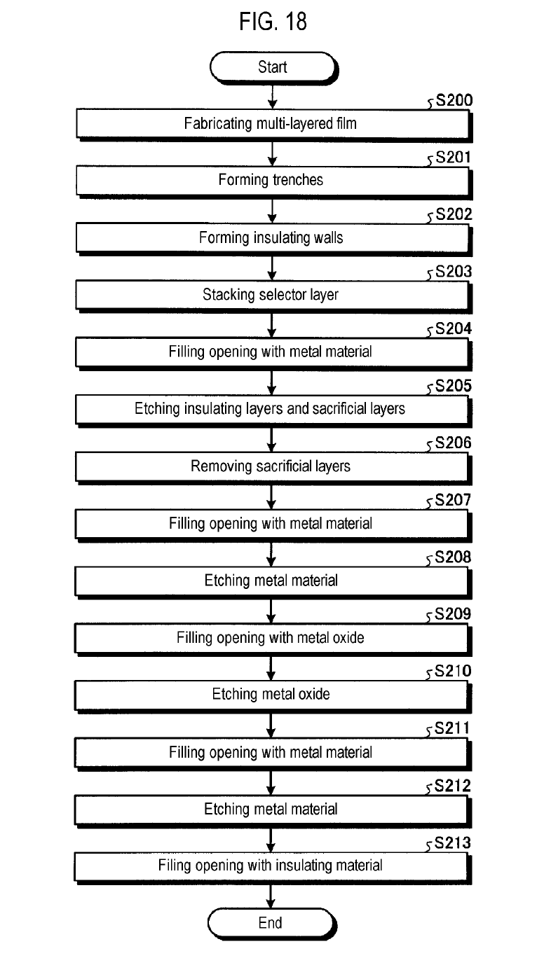

Next, a procedure for fabricating the ReRAM 10 of this embodiment will be described with reference to FIGS. 18 to 28. FIG. 18 is a flowchart showing an example of a procedure for fabricating the ReRAM 10 of the second embodiment.

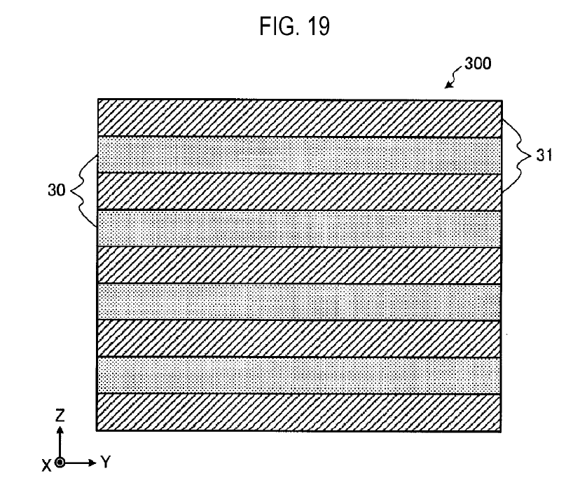

First, for example, as shown in FIG. 19, a multi-layered film 300 with sacrificial layers 30 and insulating layers 31 alternately stacked is formed (S200). In the multi-layered film 300 shown in FIG. 19, the sacrificial layer 30 is made of, for example, silicon nitride (SiN) or the like. In addition, the insulating layer 31 is made of the material used for forming the insulating layer 15, such as SiO₂ or the like. The multi-layered film 300 shown in FIG. 19 is prepared by, for example, CVD, ALD or the like. In the multi-layered film 300 shown in FIG. 19, a stacked direction is defined as the Z direction, a direction perpendicular to the paper in FIG. 19 in a plane of each layer is defined as the X direction, and a direction parallel to the paper in FIG. 19 is defined as the Y direction.

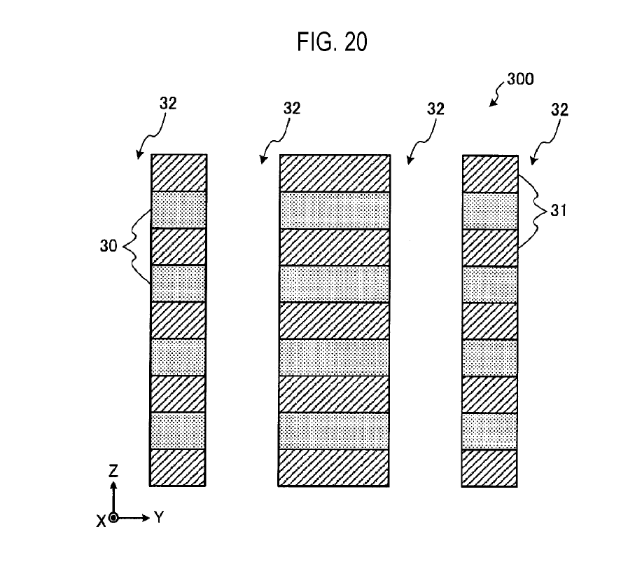

Thereafter, for example, as shown in FIG. 20, a plurality of trenches 32 extending in the X direction and the Y direction are formed in the multi-layered film 300 in the Y direction (S201). Each of the trenches 32 is formed by, for example, an isotropic etching such as RIE or the like. The trench 32 is one example of the first opening.

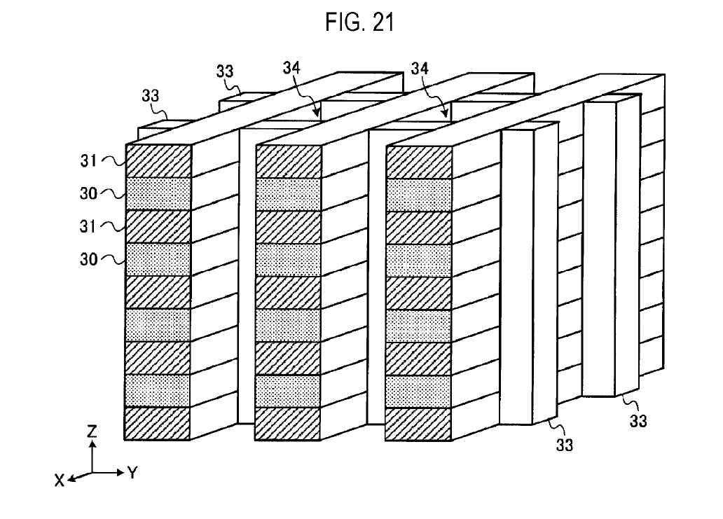

Subsequently, each of the trenches 32 is filled with an insulating material such as SiO₂ or the like. Thereafter, the insulating materials with which the trenches 32 have been filled are removed at a predetermined interval in the X direction. The insulating materials are removed by, for example, an anisotropic etching such as RIE or the like. Accordingly, for example, as shown in FIG. 21, portions of the residual insulating materials are formed as insulating walls 33 in the respective trenches 32 (S202). Further, by removing portions of the insulating materials with which the trenches 32 have been filled, a plurality of openings 34 surrounded by the multi-layered film 300 and the insulating walls 33 are formed, for example, as shown in FIG. 21. At an inner wall of each of the openings 34, the sacrificial layer 30 and the insulating layer 31 in addition to sidewalls of the insulating walls 33 are exposed.

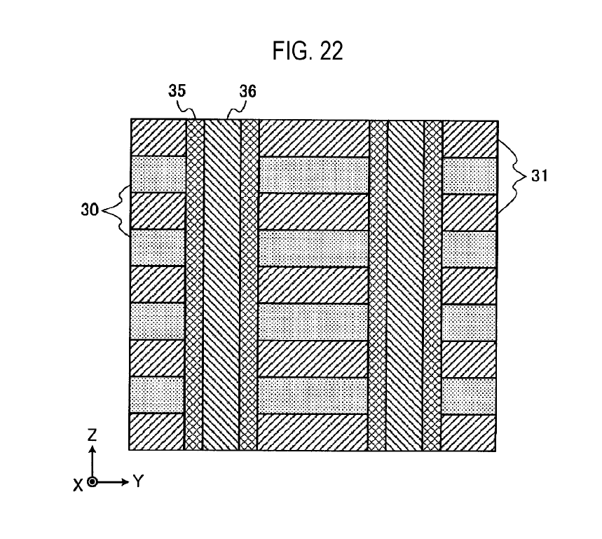

Thereafter, for example, as shown in FIG. 22, a selector layer 35 is stacked along an inner wall of each of the openings 34 (S203). The selector layer 35 is formed of, for example, the material used for forming the selector layer 12, such as a chalcogenide material or the like. The selector layer 35 is stacked along the inner wall of the opening 34 by, for example, CVD, ALD or the like. The selector layer 35 is one example of the first layer.

Subsequently, for example, as shown in FIG. 22, the opening 34 with the selector layer 35 stacked therein is filled with a metal material 36 (S204). Accordingly, the selector layer 35 and the metal material 36 are stacked on the inner wall of each of the openings 34. The metal material 36 with which the opening 34 is filled is the metal material used for forming the electrode layer 11. The metal material 36 is one example of the first material.

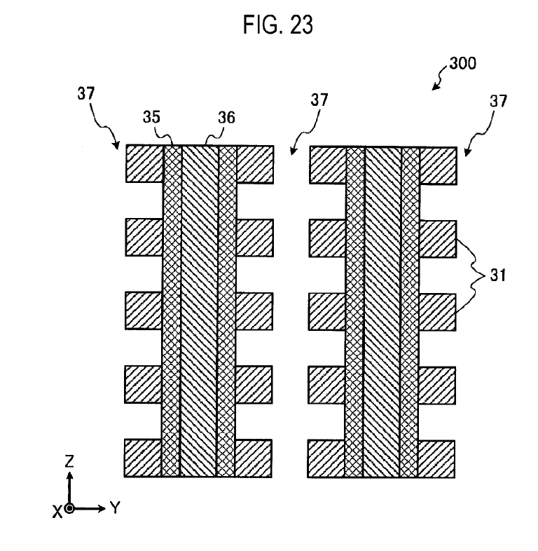

Thereafter, for example, as shown in FIG. 23, at positions different from the positions where the openings 34 are formed, the sacrificial layers 30 and the insulating layers 31 that constitute the multi-layered film 300 are etched in the Z direction to form a plurality of openings 37 opened in the X direction and the Y direction (S205). Each of the openings 37 is formed by, for example, an anisotropic etching such as RIE or the like. The opening 37 is one example of the second opening.

Subsequently, the sacrificial layers 30 are removed (S206). The sacrificial layers 30 are removed by, for example, an isotropic etching such as a wet etching.

Thereafter, the opening 37 is filled with a metal material 38 (S207). Accordingly, the areas between the insulating layers 31 where the sacrificial layers 30 had been disposed are also filled with the metal material 38. The metal material 38 with which the opening 37 is filled is the metal material used for forming the intermediate conductive layer 13. The metal material 38 is one example of the second material.

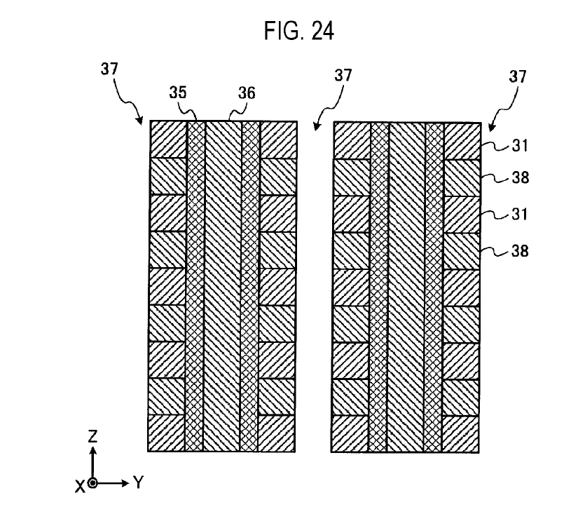

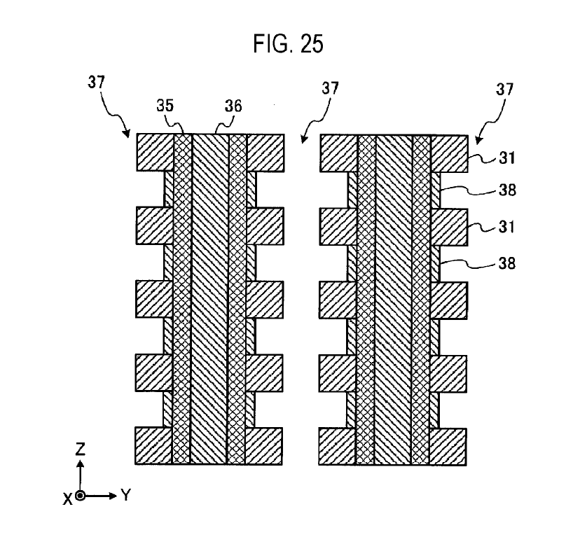

Subsequently, for example, as shown in FIG. 24, the metal material 38 is etched in the Z direction and the opening 37 is formed again (S208). In the etching in step S208, the metal material 38 is etched such that the insulating layer 31 is exposed at the inner wall of each of the openings 37. Accordingly, for example, as shown in FIG. 24, the metal materials 38 are separated from each other by the respective insulating layer 31 which are interposed between the metal materials 38 in the Z direction. Moreover, for example, as shown in FIG. 25, the metal material 38 is also etched in the X direction (S208). In step S208, an anisotropic etching such as RIE or the like is used in etching the metal materials 38 in the Z direction. An isotropic etching such as a wet etching or the like is used in etching the metal materials 38 in the X direction. In step S208, an etchant having a high selectivity for the metal material 38 relative to the insulating layer 31 is used.

Thereafter, the opening 37 is filled with a metal oxide 39 (S209). Accordingly, an area between the insulating layers 31 is filled with the metal oxide 39. The metal oxide 39 with which the opening 37 is filled is the material used for forming the resistance change layer 14, such as HfO or the like. The metal oxide 39 is one example of the third material.

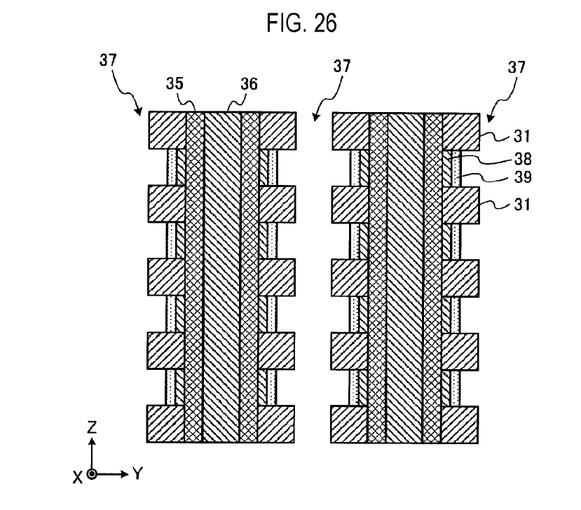

Subsequently, the metal oxide 39 is etched in the Z direction and the opening 37 is formed again (S210). In the etching in step 5210, the metal oxide 39 is etched such that the insulating layer 31 is exposed at the inner wall of each of the openings 37. Moreover, for example, as shown in FIG. 26, the metal oxide 39 is also etched in the X direction (S210). In step S210, an anisotropic etching such as RIE or the like is used in etching the metal oxides 39 in the Z direction, and an isotropic etching such as a wet etching or the like is used in etching the metal oxides 39 in the X direction. In step S210, an etchant having a high selectivity for the metal oxide 39 relative to the insulating layer 31 is used.

Thereafter, the opening 37 is filled with a metal material 40 (S211). Accordingly, an area between the insulating layers 31 is also filled with the metal material 40. The metal material 40 with which the opening 37 is filled is the metal material used for forming the electrode layer 16. The metal material 40 is one example of the fourth material.

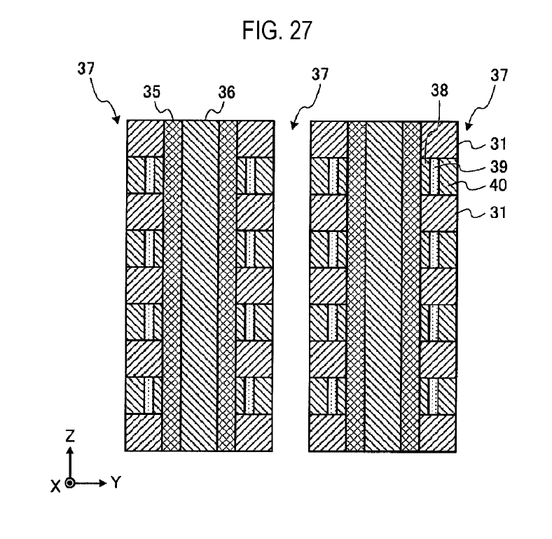

Subsequently, the metal material 40 is etched in the Z direction and the opening 37 is formed again (S212). In the etching in step S212, the metal material 40 is etched such that the insulating layer 31 is exposed at the inner wall of each of the openings 37. Accordingly, for example, as shown in FIG. 27, the metal materials 40 with which areas where the sacrificial layers 30 had been disposed are filled are separated from each other by the respective insulating layers 31. The metal material 40 is etched by, for example, an anisotropic etching such as RIE or the like using an etchant having a high selectivity for the metal material 40 relative to the insulating layer 31.

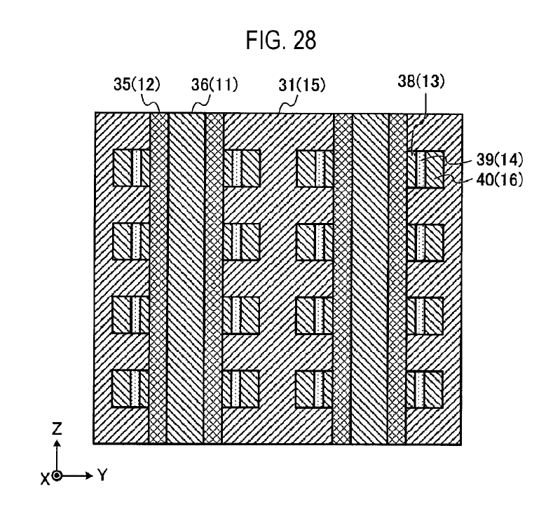

Thereafter, for example, as shown in FIG. 28, the opening 37 is filled with an insulating material such as SiO₂ or the like (S213). In this way, the ReRAM 10 of this embodiment is fabricated. In each of the memory cells 17, the metal material 36 functions as the electrode layer 11, the selector layer 35 functions as the selector layer 12 and the metal material 38 functions as the intermediate conductive layer 13. Moreover, in each of the memory cells 17, the metal oxide 39 functions as the resistance change layer 14, the insulating layer 31 functions as the insulating layer 15 and the metal material 40 functions as the electrode layer 16.

The ReRAM 10 according to the second embodiment has been described above. As is apparent from the foregoing description, according to the ReRAM 10 of this embodiment, the intermediate conductive layers 13 in the respective memory cells 17 are electrically insulated from one another by the respective insulating layers 15. Therefore, a current flowing from each of the electrode layers 16 to the electrode layer 11 through the resistance change layer 14, the intermediate conductive layer 13 and the selector layer 12 does not flow into another intermediate conductive layer 13. Accordingly, a current corresponding to a resistance value of the intermediate conductive layer 13 in the selected memory cell 17 is detected in the electrode layer 11, so that information set in the respective memory cell 17 is correctly read out.

Furthermore, since the intermediate conductive layers 13 in the respective memory cells 17 are electrically insulated from one another by the respective insulating layers 15, it is possible to suppress a leakage current through a selector layer 12 located at a position corresponding to a non-selected electrode layer 16. As a result, a current corresponding to a resistance value of the intermediate conductive layer 13 in the selected memory cell 17 is detected in the electrode layer 11, so that information set in the respective memory cell 17 is correctly read out. In addition, the suppression of the leakage current restrains power consumption of the ReRAM 10.

In each of the memory cells 17 of the ReRAM 10 according to the embodiment, the intermediate conductive layer 13 is disposed between the selector layer 12 and the resistance change layer 14, so that the selector layer 12 is not in direct contact with the resistance change layer 14. Accordingly, a reaction between an element contained in the selector layer 12 and an element contained in the resistance change layer 14 is suppressed so that changes in the selector layer 12 and the resistance change layer 14 are also suppressed. As a result, the deterioration of the switching property of the selector layer 12 and the reduction in the ratio of the resistance values of the resistance change layer 14 are suppressed.

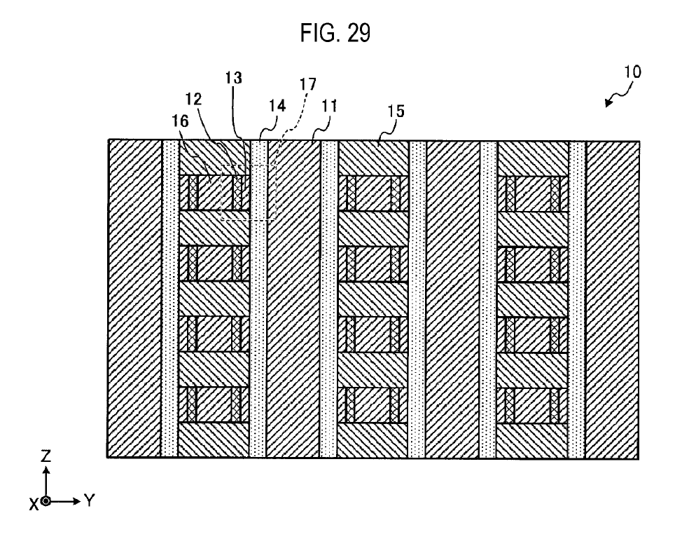

In each of the memory cells 17 of the ReRAM 10 according to the second embodiment described above, for example, as shown in FIGS. 16 and 17, the resistance change layer 14 is disposed towards the side closer to the electrode layer 16 and the selector layer 12 is disposed towards the side closer to the electrode layer 11 with the intermediate conductive layer 13 disposed between the resistance change layer 14 and the selector layer 12. However, the technique disclosed herein is not limited thereto. As an example, as shown in FIG. 29, in each of the memory cells 17, the selector layer 12 may be disposed towards the side closer to the electrode layer 16 and the resistance change layer 14 may be disposed towards the side closer to the electrode layer 11 with the intermediate conductive layer 13 disposed between the selector layer 12 and the resistance change layer 14.

### [Others]

The present disclosure is not limited to the aforementioned embodiments, and various modifications may be made within the scope of the present disclosure.

As an example, if the fabricating procedure of the ReRAM 10 according to the first embodiment is a procedure capable of fabricating the ReRAM 10 shown in FIGS. 1 and 2, it is not limited to the procedure illustrated in FIG. 3. Moreover, if the fabricating procedure of the ReRAM 10 according to the second embodiment is a procedure capable of fabricating the ReRAM 10 shown in FIGS. 16 and 17, it is not limited to the procedure illustrated in FIG. 18.

For example, while in the second embodiment, the ReRAM 10 has been described to be fabricated using the multi-layered film 300 with the sacrifice layers 30 and the insulating layers 31 alternately stacked, the present disclosure is not limited thereto. Alternately, a multi-layered film with conductive metal layers and insulating layers alternately stacked may be used to fabricate the ReRAM 10. In this case, steps S206 to S208 may be omitted in the fabricating procedure shown in FIG. 18.

According to various aspects and embodiments of the present disclosure, it is possible to correctly read out information set in each of the memory cells of a vertical ReRAM.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A nonvolatile storage device, comprising:
a plurality of first wirings arranged in a first direction and a second direction that intersect each other, and extending in a third direction perpendicular to the first direction and the second direction;
a plurality of second wirings extending in the first direction, and each of the plurality of second wiring installed at a predetermined interval from each other in the third direction;
a plurality of first layers disposed between the plurality of first wirings and the plurality of second wirings, and extending in the third direction along the plurality of first wirings; and
a plurality of memory cells installed between the plurality of first layers and the plurality of second wirings and at respective positions where the plurality of first layers and the plurality of second wirings intersect each other,
wherein each of the plurality of memory cells includes a second layer disposed towards a second wiring side closer to the plurality of second wirings and a conductive intermediate layer disposed towards a first layer side closer to the plurality of first layers,
the intermediate layer in one of the memory cells is insulated from the intermediate layer in another memory cell of the memory cells adjacent to the one of the memory cells by an insulating layer,
each of the plurality of first layers is one of a memory layer configured to hold a resistance value that changes depending on a voltage applied, as a data, and a selector layer configured to control a selection and a non-selection of each of the plurality of memory cells, and
the second layer is the other of the memory layer and the selector layer.

2. The nonvolatile storage device of claim 1, wherein:
the plurality of memory cells are insulated from one another by insulating layers, and
the second layer in each of the plurality of memory cells is disposed between the intermediate layer and the second wiring and between the intermediate layer and the insulating layer.

3. The nonvolatile storage device of claim 1, wherein in each of the plurality of memory cells, the intermediate layer is interposed between the first layer and the second layer.

4. A method of fabricating a nonvolatile storage device, comprising:
forming an opening in a multi-layered film in a stacked direction of the multi-layered film, the multi-layered film having a plurality of insulating layers and a plurality of metal layers alternately stacked;
etching the plurality of metal layers on an inner wall of the opening in a plane direction of the multi-layered film;
stacking a first layer along the inner wall of the opening;
filling the opening with a first conductive material;
etching the first conductive material filled into the opening so that the plurality of insulating layers are exposed, and forming the opening again;
stacking a second layer along the inner wall of the opening; and
filling the opening with a second conductive material,
wherein the first layer is one of a memory layer configured to hold a resistance value that changes depending on a voltage applied thereto, as data, and a selector layer configured to control a selection and a non-selection of the memory layer, and
the second layer is the other of the memory layer and the selector layer.

5. A method of fabricating a nonvolatile storage device, comprising:
forming a first opening in a multi-layered film in a stacked direction of the multi-layered film, the multi-layered film having a plurality of insulating layers and a plurality of sacrificial layers alternately stacked;
stacking a first layer along an inner wall of the first opening;
filling the first opening with a first conductive material;
forming a second opening in the multi-layered film in the stacked direction of the multi-layered film, the second opening being formed at a second position different from a first position where the first opening is formed;
removing the plurality of sacrificial layers;
filling areas between the plurality of insulating layers where the plurality of sacrificial layers had been disposed, with a second conductive material;
etching the second conductive material at the second position, so that the plurality of insulating layers are exposed, and forming the second opening again;
etching the second conductive material on an inner wall of the second opening in a plane direction of the multi-layered film;
filling areas between the plurality of insulating layers with a third material for forming a second layer in the second opening;
etching the third material filled into the second opening, so that the plurality of insulating layers are exposed, and forming the second opening again;
etching the third material on the inner wall of the second opening in the plane direction of the multi-layered film, to form the second layer;
filling the second opening with a fourth conductive material;
etching the fourth conductive material at the second position, so that the plurality of insulating layers are exposed, and forming the second opening again; and
filling the second opening with an insulating material,
wherein the first layer is one of a memory layer configured to hold a resistance value that changes depending on a voltage applied, as a data, and a selector layer configured to control a selection and a non-selection of the memory layer, and
the second layer is the other of the memory layer and the selector layer.
